(19) United States
(12) Patent Application Publication
(10) Pub. No.: US 2025/0211122 A1
(43) Pub. Date: Jun. 26, 2025

(54) POWER CONVERTER AND CURRENT DETECTION CIRCUIT

(71) Applicant: KABUSHIKI KAISHA TOYOTA JIDOSHOKKI, Aichi (JP)

(72) Inventor: Nobuo HIRABAYASHI, Aichi (JP)

(73) Assignee: KABUSHIKI KAISHA TOYOTA JIDOSHOKKI, Aichi (JP)

(21) Appl. No.: 18/985,147

(22) Filed: Dec. 18, 2024

(30) Foreign Application Priority Data
Dec. 20, 2023 (JP) 2023-214377

(51) Int. Cl. H02M 3/335; H02M 1/00

(52) U.S. Cl. CPC H02M 3/33569; H02M 1/0009

(57) ABSTRACT

A power converter including a coil includes a detection coil that is magnetically coupled to the coil, a detection resistor and a detection capacitor that are connected in series to each other and in parallel to the detection coil, and a detection circuit that detects a current flowing through the coil based on a voltage across the detection capacitor.

### CROSS-REFERENCE OF THE RELATED APPLICATION

This application claims priority to Japanese Patent Application No. 2023-214377 filed on Dec. 20, 2023, the entire disclosure of which is incorporated herein by reference.

### BACKGROUND ART

The present disclosure relates to a technique for detecting a current flowing through a coil provided in a power converter.

There is known a current detection circuit in which a coil provided in a power converter is connected in parallel to a detection resistor and a detection capacitor connected in series to each other, and a detection circuit is connected to both terminals of the detection capacitor. The detection circuit detects a current flowing through the coil based on a drop voltage of a direct current (DC) resistance component of the coil, which is obtained by a voltage across the detection capacitor, and corrects the detected current based on an error between the voltage across the detection capacitor and the drop voltage. Japanese Patent Application Publication No. 2000-193687 is a prior art related to the above-described current detection circuit.

However, in the above-described current detection circuit, the detection capacitor is directly connected to the coil. For this reason, when the current flowing through the coil is detected based on the drop voltage of the DC resistance component of the coil, it is required to offset a reference potential of the detection circuit based on the voltage across the detection capacitor or to offset the voltage across the detection capacitor based on the reference potential of the detection circuit. Accordingly, manufacturing costs may increase as much as a cost of addition of a function for offsetting the reference potential of the detection circuit or the voltage across the detection capacitor to the detection circuit. In addition, since the drop voltage is a relatively small value, the drop voltage is easily affected by quantization error in the detection circuit when an analog value is converted to a digital value in the drop voltage. This may reduce a detection accuracy of the current.

The present disclosure is partially directed to suppressing manufacturing costs of a power converter while a detection accuracy of a current flowing through a coil provided in the power converter is improved.

### SUMMARY

In accordance with an aspect of the present disclosure, a power converter including a coil includes a detection coil that is magnetically coupled to the coil, a detection resistor and a detection capacitor that are connected in series to each other and in parallel to the detection coil, and a detection circuit that detects a current flowing through the coil based on a voltage across the detection capacitor.

In accordance with another aspect of the present disclosure, a current detection circuit for detecting a current flowing through a coil provided in a power converter includes a detection coil that is magnetically coupled to the coil, a detection resistor and a detection capacitor that are connected in series to each other and in parallel to the detection coil, and a detection circuit that detects a current flowing through the coil based on a voltage across the detection capacitor.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a diagram illustrating an example of a power converter according to an embodiment;

FIG. 2 is a view illustrating an example of a smoothing coil, a core, and a detection coil;

FIG. 3 is a diagram illustrating a first modification of the power converter according to the embodiment;

FIG. 4 is a diagram illustrating a second modification of the power converter according to the embodiment;

FIG. 5 is a diagram illustrating a third modification of the power converter according to the embodiment;

FIG. 6 is a diagram illustrating a fourth modification of the power converter according to the embodiment;

FIG. 7 is a diagram illustrating a fifth modification of the power converter according to the embodiment; and

FIG. 8 is a diagram illustrating a sixth modification of the power converter according to the embodiment.

### DETAILED DESCRIPTION OF THE EMBODIMENTS

The following will describe an embodiment in detail with reference to the drawings.

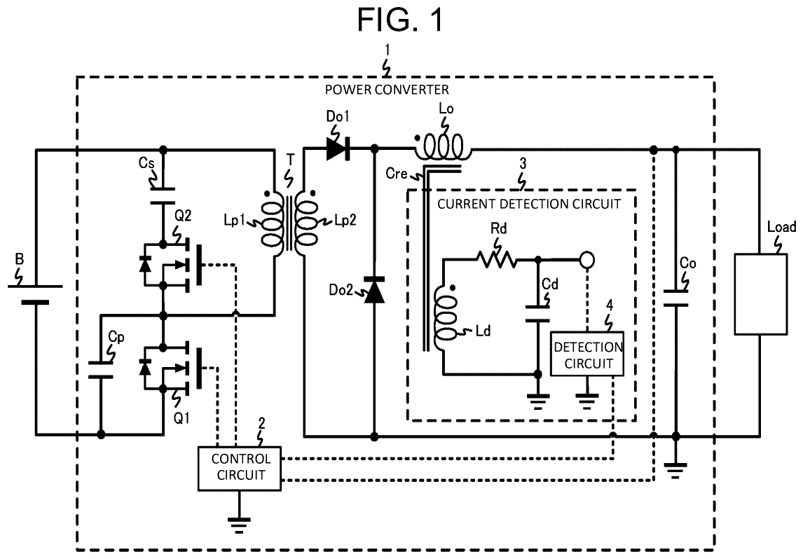

FIG. 1 is a diagram illustrating an example of a power converter according to a present embodiment.

A power converter 1 illustrated in FIG. 1 is an active clamp forward converter, and converts a DC power output from a power supply B to a specified DC power and supplies the specified DC power to a load.

The power converter 1 includes switches Q1, Q2, capacitors Cp, Cs, a transformer T, diodes Do1, Do2, a smoothing coil Lo, a smoothing capacitor Co, a control circuit 2, and a current detection circuit 3. Note that the switches Q1, Q2 are each formed of a metal oxide semiconductor field effect transistor (MOSFET), for example. A drain terminal of the switch Q1 is connected to one terminal of the capacitor Cp, a source terminal of the switch Q2, and one terminal of a primary coil Lp1 of the transformer T. A source terminal of the switch Q1 is connected to the other terminal of the capacitor Cp and a negative terminal of the power supply B. A drain terminal of the switch Q2 is connected to a positive terminal of the power supply B and the other terminal of the primary coil Lp1 through the capacitor Cs. A cathode terminal of the diode Do1 is connected to a cathode terminal of the diode Do2. The cathode terminal of the diode Do1 is also connected to one terminal of the smoothing capacitor Co and one terminal of the load through the smoothing coil Lo. An anode terminal of the diode Do1 is connected to one terminal of a secondary coil Lp2 of the transformer T. An anode terminal of the diode Do2 is connected to the other terminal of the secondary coil Lp2, the other terminal of the smoothing capacitor Co, and the other terminal of the load.

For example, the control circuit 2 is formed of a central processing unit (CPU), a multi-core CPU, or a programmable device such as a field programmable gate array (FPGA) or a programmable logic device (PLD).

When the power converter 1 converts the DC power output from the power supply B to the specified DC power and supplies the specified DC power to the load, the switches Q1, Q2 are turned on and off alternately and repeatedly by the control circuit 2 so that a voltage across the smoothing capacitor Co reaches a target voltage and a current detected by the current detection circuit 3 reaches a target current.

First, when the switch Q1 is turned on (when the switch Q1 is in an on-state and the switch Q2 is in an off-state), a current flows from the power supply B to the primary coil Lp1, and a current flows from the secondary coil Lp2 to the load through the diode Do1 and the smoothing coil Lo.

Next, when the switch Q1 is turned off (when the switches Q1, Q2 are in the off-state (deadtime)), a current flows from the primary coil Lp1 to the capacitor Cp to charge the capacitor Cp. When the voltage across the capacitor Cp reaches a total voltage of a voltage of the power supply B and a voltage across the capacitor Cs, a current flows from the primary coil Lp1 into the capacitor Cs through a body diode of the switch Q2 to charge the capacitor Cs. On a side of the load, the current continuously flows from the diode Do1 to the load through the smoothing coil Lo. Note that energy stored in the primary coil Lp1 is reduced by charging the capacitors Cp, Cs, so that the transformer T in a magnetic saturation state is gradually demagnetized. Furthermore, when the switch Q1 is turned off, the voltage across the capacitor Cp is 0 [V], and thus, a switching loss is reduced.

Next, when the switch Q2 is turned on (when the switch Q1 is in the off-state and the switch Q2 is in the on-state), a current flows from the primary coil Lp1 into the capacitor Cs through the switch Q2 to charge the capacitor Cs. In addition, on the side of the load, a current flows from the diode Do2 to the load through the smoothing coil Lo. Note that the energy stored in the primary coil Lp1 is further reduced by charging the capacitor Cs, so that the transformer T in the magnetic saturation state is gradually demagnetized. Furthermore, when the switch Q2 is turned on, a current flows through the body diode of the switch Q2, and thus, the switching loss is reduced. Then, while the switch Q2 is in the on-state, a direction of the current is reversed and the capacitor Cs is discharged.

Next, when the switch Q2 is turned off (when the switches Q1, Q2 are in the off-state (deadtime)), a current flows from the capacitor Cp to the power supply B through the primary coil Lp1, that is, the capacitor Cp is discharged. After the capacitor Cp is discharged, a current flows from the body diode of the switch Q1 toward the power supply B through the primary coil Lp1. In addition, on the side of the load, the current continuously flows from the diode Do2 to the load through the smoothing coil Lo.

After that, the switches Q1, Q2 are turned on and off alternately and repeatedly. Note that, when the switch Q1 is turned on, the current flows through the body diode of the switch Q1, and thus, the switching loss is reduced.

The current detection circuit 3 includes a detection coil Ld, a detection resistor Rd, a detection capacitor Cd, and a detection circuit 4. The current detection circuit 3 detects a current (alternating current) flowing through the smoothing coil Lo.

The detection coil Ld is wound around a core Cre of the smoothing coil Lo, and thus, the detection coil Ld is magnetically coupled to the smoothing coil Lo. Note that in a case where the number of turns of the smoothing coil Lo is represented as N1 and the number of turns of the detection coil Ld is represented as N2, a turns ratio N2/N1 is preferably equal to or more than 0.3 and equal to or less than 10. Furthermore, the turns ratio N2/N1 is more preferably equal to or more than 1 and equal to or less than 10. Hereinafter, the turns ratio N2/N1 is also referred to as the turns ratio n. Thus, a voltage across the detection capacitor Cd increases by setting the turns ratio n relatively large, so that the voltage across the detection capacitor Cd is not easily affected by quantization error in the detection circuit 4 when an analog value is converted to a digital value in the voltage across the detection capacitor Cd. This may improve a detection accuracy of the current.

The detection resistor Rd and detection capacitor Cd are connected in series to each other and are connected in parallel to the detection coil Ld. That is, one terminal of the detection capacitor Cd is connected to one terminal of the detection coil Ld through the detection resistor Rd, and the other terminal of the detection capacitor Cd is connected to the other terminal of the detection coil Ld and a reference potential of the detection circuit 4 (for example, a ground of the power converter 1).

The detection circuit 4 detects the current flowing through the smoothing coil Lo based on the voltage across the detection capacitor Cd (a difference between an electric potential at the one terminal of the detection capacitor Cd and the reference potential of the detection circuit 4).

For example, a voltage across the smoothing coil Lo is represented as VL, the current flowing through the smoothing coil Lo is represented as iL, an inductance of the smoothing coil Lo is represented as L, the voltage across the detection capacitor Cd is represented as Vc, a capacitance of the detection capacitor Cd is represented as C, a voltage across the detection resistor Rd is Vr, a resistance of the detection resistor Rd is represented as R, a current flowing through the detection capacitor Cd and the detection resistor Rd is represented as is, a ratio of the number of turns of the detection coil Ld to the number of turns of the smoothing coil Lo is represented as n, and a Laplace operator is represented as s. In this case, a voltage VLd across the detection coil Ld is expressed by the following equation:

$$VLd = Vc + Vr$$

where VLd=n×VL=s×n×L×iL is satisfied, Vc=is/(s×C) is satisfied, and Vr=R×is is satisfied. Accordingly, the above-described equation is expressed by the following equation:

$$s \times n \times L \times iL = is / ( s \times C ) + R \times is$$

When this equation is solved for the current is, the current is is expressed by the following equation:

$$is = ( s \times n \times L ) / ( 1 / ( s \times C ) + R ) \times iL$$

Thus, the voltage Vr is expressed by the following equation:

$$Vr = R \times is = R \times ( s \times n \times L ) / ( 1 / ( s \times C ) + R ) \times iL$$

As a result, the voltage Vc of the detection capacitor Cd is expressed as the following Equation 1.

$$\begin{matrix}Vc = VLd - Vr \\ = s \times n \times L \times iL - R \times ( s \times n \times L ) / ( 1 / ( s \times C ) + R ) \times iL \\ = ( s \times n \times L \times iL ) / ( 1 + s \times C \times R )\end{matrix} \qquad ( Equation 1 )$$

Here, a cutoff frequency fc in a filter circuit formed of the detection resistor Rd and the detection capacitor Cd is expressed by the following equation: fc=1/(2π×R×C). When the resistance R of the detection resistor Rd and the capacitance C of the detection capacitor Cd are set such that the cut off frequency fc is sufficiently smaller than a switching frequency of the power converter 1, the condition that s×C×R>>1 is satisfied. Then, the “1” in the denominator of Equation 1 above can be ignored, so that Equation 1 is transformed into the following Equation 2.

$$Vc = ( n \times L \times iL ) / ( C \times R ) \qquad ( Equation 2 )$$

That is, in the detection circuit 4, the current iL flowing through the smoothing coil Lo is obtained by substituting the voltage Vc across the detection capacitor Cd to the above-described Equation 2. Note that the turns ratio n, the inductance L, the capacitance C, and the resistance R are each a predetermined value.

Thus, according to the power converter 1 in the embodiment, since the detection coil Ld is magnetically coupled to the smoothing coil Lo, the smoothing coil Lo and the detection capacitor Cd are electrically separated (insulated) from each other. This may set a reference potential of the detection capacitor Cd as desired, independently of the smoothing coil Lo. For this reason, when the other terminal (reference potential) of the detection capacitor Cd is connected to the reference potential of the detection circuit 4, the current iL flowing through the smoothing coil Lo is detected based on the voltage Vc across the detection capacitor Cd without offsetting the reference voltage of the detection circuit 4 or the voltage across the detection capacitor Cd. As a result, the power converter 1 need not have a function for offsetting the reference potential of the detection circuit 4 or the voltage across the detection capacitor Cd, so that an increase of manufacturing costs of the power converter 1 is suppressed. In addition, the current iL flowing through the smoothing coil Lo need not be corrected after being detected, and thus, an increase of a detection time of the current iL is suppressed.

The current detection circuit 3 may be formed so as to detect a current flowing through the primary coil Lp1 or the secondary coil Lp2 having a core. When the current detection circuit 3 detects the current flowing through the primary coil Lp1 or secondary coil Lp2, the detection coil Ld is formed by being wound around the core of the primary coil Lp1 or secondary coil Lp2. In addition, when the detection circuit 4 detects the current flowing through the primary coil Lp1 or the secondary coil Lp2 based on the voltage across the detection capacitor Cd, in above-described Equation 2, the turns ratio n represents a ratio of the number of turns of the detection coil Ld to the number of turns of the primary coil Lp1 or the secondary coil Lp2, and the inductance L represents an inductance of the primary coil Lp1 or the secondary coil Lp2.

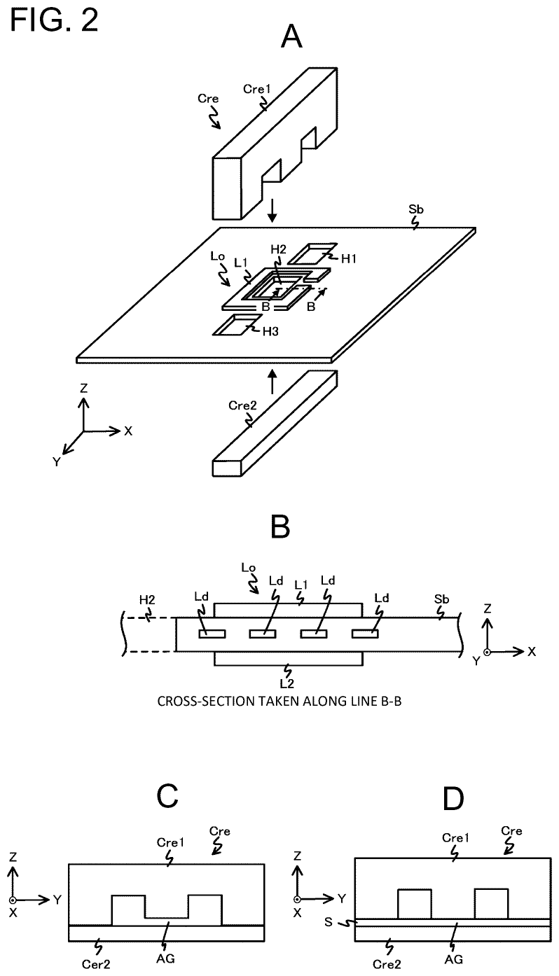

Here, FIG. 2A to 2D each illustrate an example of the smoothing coil Lo, the detection coil Ld, and the core Cre. FIG. 2A is a perspective view illustrating a multilayer printed circuit board (PCB) Sb on which the power converter 1 is mounted, the smoothing coil Lo, and the core Cre. FIG. 2B is a cross-sectional view illustrating the multilayer PCB Sb, the smoothing coil Lo, and the detection coil Ld. FIG. 2C illustrates an example of the core Cre, and FIG. 2D illustrates another example of the core Cre.

The smoothing coil Lo illustrated in FIG. 2A and FIG. 2B is formed of plate-shaped conductors L1, L2 each having a C-shape. The plate-shaped conductor L1 is disposed on one main surface (a surface oriented toward a positive side in a Z-direction) of the multilayer PCB Sb and the plate-shaped conductor L2 is disposed on the other main surface (a surface oriented toward a negative side in the Z-direction) of the multilayer PCB Sb. For example, one terminal of the plate-shaped conductor L1 is connected to a wiring pattern on the one main surface of the multilayer PCB Sb by soldering and the other terminal of the plate-shaped conductor L1 is connected to one terminal of the plate-shaped conductor L2 through a conductor in the multilayer PCB Sb. The other terminal of the plate-shaped conductor L2 is connected to a wiring pattern on the other main surface of the multilayer PCB Sb by soldering. Thus, the plate-shaped conductor L1 and the plate-shaped conductor L2 are connected in series to each other and form the smoothing coil Lo of two turns. Note that the smoothing coil Lo may be formed of only the plate-shaped conductor L1 or only the plate-shaped conductor L2. That is, the smoothing coil Lo is disposed at least one of the main surfaces of the multilayer PCB Sb on which the power converter 1 is mounted.

In addition, the detection coil Ld illustrated in FIG. 2B is an accumulated coil formed of a wiring pattern, and disposed on an inner layer of the multilayer PCB Sb such that the detection coil Ld faces the smoothing coil Lo in a thickness direction (Z-direction) of the multilayer PCB Sb. In FIG. 2B, the detection coil Ld is formed of the wiring pattern which spirally turns four times; however, the number of turns is not limited to four. Note that the detection coil Ld may be disposed on at least one of the main surfaces of the multilayer PCB Sb. That is, the detection coil Ld is arranged relative to the smoothing coil Lo in the thickness direction of the multilayer PCB Sb. Furthermore, the detection coil Ld is not limited to a configuration in which the detection coil Ld is disposed on the one inner layer of the multilayer PCB Sb. The detection coil Ld may be formed by connecting winding patterns in series to each other, which are each formed on a corresponding plurality of inner layers. In addition, the detection coil Ld may be formed of a conductive wire, or the like, and detection coil is not limited to the wiring pattern. The PCB on which the power converter 1 is mounted need not be formed of the multilayer PCB.

The core Cre illustrated in FIG. 2A is formed of a magnetic body Cre1 having an E-shape and a magnetic body Cre2 having an I-shape. Three through holes H1 to H3 are arranged in a Y-direction in the multilayer PCB Sb. The through hole H2 is disposed inside the smoothing coil Lo, and the through holes H1, H3 are disposed outside the smoothing coil Lo. Three protrusions of the magnetic body Cre1 are each inserted into the corresponding through holes H1 to H3 and joined to the magnetic body Cre2 to form the core Cre.

Note that as illustrated in FIG. 2C, in the core Cre, when the magnetic body Cre1 and the magnetic body Cre2 are joined to each other, at least one of the three protrusions of the magnetic body Cre1 may be shortened such that a distal end of the protrusion does not come in contact with the magnetic body Cre2, which forms a gap AG.

Alternatively, as illustrated in FIG. 2D, in the core Cre, the gap AG may be formed by connecting the three protrusions of the magnetic body Cre1 to the magnetic body Cre2 through a spacer S.

Also, there may be no gap in the core Cre.

The present disclosure is not limited to the above-described embodiment, and may be improved or modified within a gist of the present disclosure.

The power converter 1 of the embodiment is not limited to the active clamp forward converter and may be another converter.

### <First Modification>

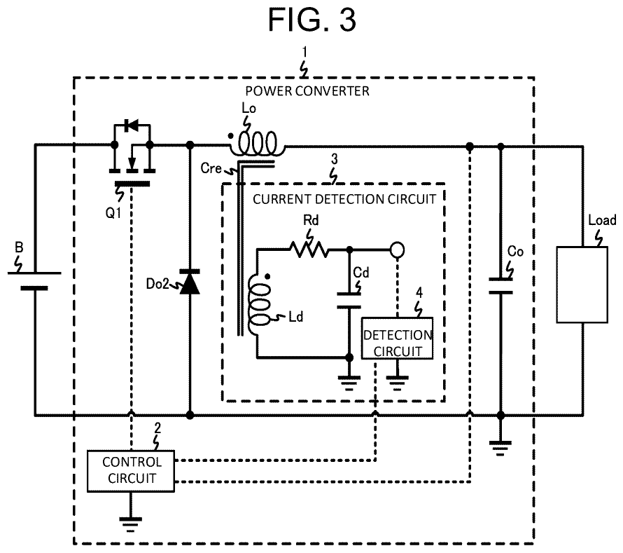

FIG. 3 is a diagram illustrating a first modification of the power converter 1 according to the embodiment. In FIG. 3, the same components as those illustrated in FIG. 1 have the same reference numerals and may not be reiterated.

The power converter 1 illustrated in FIG. 3 is a non-isolated step-down converter, and converts a DC power output from the power supply B to a specified DC power and supplies the specified DC power to the load.

That is, the power converter 1 illustrated in FIG. 3 includes the switch Q1, the diode Do2, the smoothing coil Lo, the smoothing capacitor Co, the control circuit 2, and the current detection circuit 3. The drain terminal of the switch Q1 is connected to the positive terminal of power supply B. The source terminal of switch Q1 is connected to the cathode terminal of diode Do2 and to the one terminal of smoothing capacitor Co and the one terminal of the load through the smoothing coil Lo. The anode terminal of the diode Do2 is connected to the negative terminal of the power supply B, the other terminal of the smoothing capacitor Co, and the other terminal of the load. Note that a configuration and operation of the current detection circuit 3 illustrated in FIG. 3 are the same as those of the current detection circuit 3 illustrated in FIG. 1, and thus, the description of the configuration and the operation will be omitted. In addition, a voltage across the load is lower than a voltage of the power supply B, and thus, even when the load is formed of a battery, a current does not flow from the load to the power supply B through the body diode of the switch Q1.

When the power converter 1 converts the DC power output from the power supply B to the specified DC power and supplies the specified DC power to the load, the switch Q1 is turned on and off repeatedly by the control circuit 2 illustrated in FIG. 3 so that a voltage across the smoothing capacitor Co reaches a target voltage and a current detected by the current detection circuit 3 reaches a target current. When the switch Q1 is turned on, a current flows from the power supply B to the load through the switch Q1 and the smoothing coil Lo. In addition, when the switch Q1 is turned off, the current continuously flows from the diode Do2 to the load through the smoothing coil Lo.

Also in the power converter 1 illustrated in FIG. 3, when the detection circuit 4 detects the current flowing through the smoothing coil Lo, the power converter 1 need not have the function for offsetting a reference potential of the detection circuit 4 or a voltage across the detection capacitor Cd, so that the increase of the manufacturing costs of the power converter 1 is suppressed. In addition, also in the power converter 1 illustrated in FIG. 3, the voltage across the detection capacitor Cd increases as the turns ratio n increases, so that the voltage across the detection capacitor Cd is not easily affected by the quantization error in the detection circuit 4 when an analog value is converted to a digital value in the voltage across the detection capacitor Cd. This may improve the detection accuracy of the current. Also in the power converter 1 illustrated in FIG. 3, the current iL flowing through the smoothing coil Lo need not be corrected after being detected, and thus, the increase of the detection time of the current iL is suppressed.

### <Second Modification>

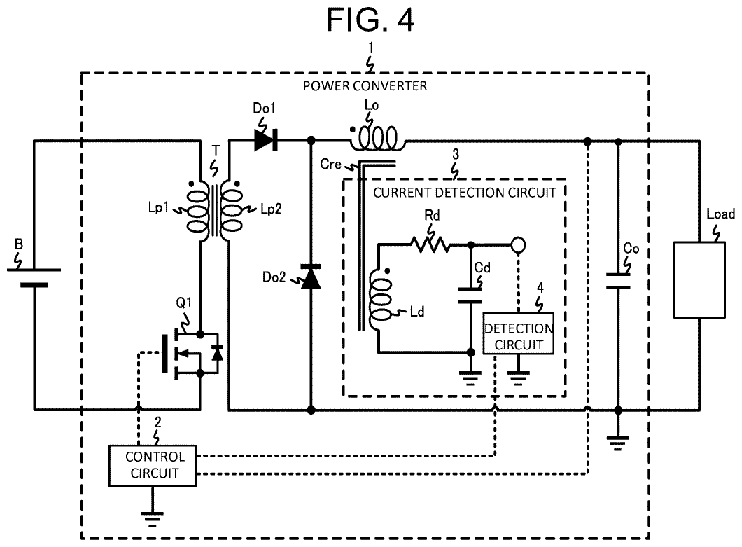

FIG. 4 is a diagram illustrating a second modification of the power converter 1 according to the embodiment. In FIG. 4, the same components as those illustrated in FIG. 1 have the same reference numerals and may not be reiterated.

The power converter 1 illustrated in FIG. 4 is an isolated forward converter, and converts a DC power output from the power supply B to a specified DC power and supplies the specified DC power to the load.

That is, the power converter 1 illustrated in FIG. 4 includes the switch Q1, the transformer T, the diodes Do1, Do2, the smoothing coil Lo, the smoothing capacitor Co, the control circuit 2, and the current detection circuit 3. The drain terminal of the switch Q1 is connected to the positive terminal of the power supply B through the primary coil Lp1 of the transformer T, and the source terminal of the switch Q1 is connected to the negative terminal of the power supply B. Note that a circuit configuration for resetting the transformer T is omitted in the isolated forward converter illustrated in FIG. 4. In addition, a configuration and operation of the current detection circuit 3 illustrated in FIG. 4 are the same as those of the current detection circuit 3 illustrated in FIG. 1, and thus, the description of the configuration and the operation will be omitted.

When the power converter 1 converts the DC power output from the power supply B to the specified DC power and supplies the specified DC power to the load, the switch Q1 is turned on and off repeatedly by the control circuit 2 illustrated in FIG. 4 so that a voltage across the smoothing capacitor Co reaches a target voltage and a current detected by the current detection circuit 3 reaches a target current. When the switch Q1 is turned on, a current flows from the power supply B to the primary coil Lp1, and a current flows from the secondary coil Lp2 of the transformer T to the load through the diode Do1 and the smoothing coil Lo. Then, when the switch Q1 is turned off, the current continuously flows from the diode Do2 to the load through the smoothing coil Lo.

Also in the power converter 1 illustrated in FIG. 4, when the detection circuit 4 detects the current flowing through the smoothing coil Lo, the power converter 1 need not have the function for offsetting a reference potential of the detection circuit 4 or a voltage across the detection capacitor Cd, so that the increase of the manufacturing costs of the power converter 1 is suppressed. In addition, also in the power converter 1 illustrated in FIG. 4, the voltage across the detection capacitor Cd increases as the turns ratio n increases, so that the voltage across the detection capacitor Cd is not easily affected by the quantization error in the detection circuit 4 when an analog value is converted to a digital value in the voltage across the detection capacitor Cd. This may improve the detection accuracy of the current. Also in the power converter 1 illustrated in FIG. 4, the current iL flowing through the smoothing coil Lo need not be corrected after being detected, and thus, the increase of the detection time of the current iL is suppressed.

### <Third Modification>

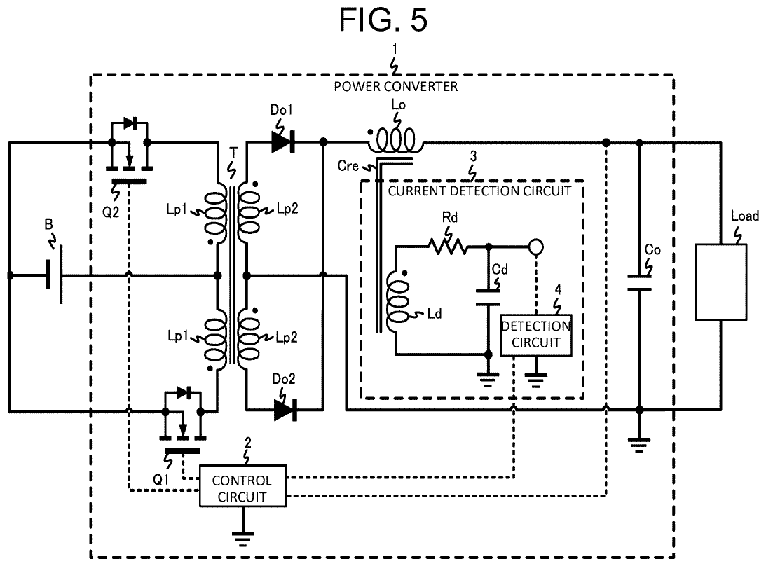

FIG. 5 is a diagram illustrating a third modification of the power converter 1 according to the embodiment. In FIG. 5, the same components as those illustrated in FIG. 1 have the same reference numerals and may not be reiterated.

The power converter 1 illustrated in FIG. 5 is an isolated push-pull converter, and converts a DC power output from the power supply B to a specified DC power and supplies the specified DC power to the load.

That is, the power converter 1 illustrated in FIG. 5 includes the switches Q1, Q2, the transformer T, the diodes Do1, Do2, the smoothing coil Lo, the smoothing capacitor Co, the control circuit 2, and the current detection circuit 3. The source terminal of the switch Q1 is connected to the negative terminal of the power supply B, and the drain terminal of the switch Q1 is connected to the one terminal of the primary coil Lp1 of the transformer T. The source terminal of the switch Q2 is connected to the negative terminal of the power supply B, and the drain terminal of the switch Q2 is connected to the other terminal of the primary coil Lp1 of the transformer T. The positive terminal of the power supply B is connected to a center tap of the primary coil Lp1. The cathode terminal of the diode Do1 is connected to the cathode terminal of the diode Do2. The cathode terminal of the diode Do1 is also connected to the one terminal of the smoothing capacitor Co and the one terminal of the load through the smoothing coil Lo. The anode terminal of the diode Do1 is connected to the one terminal of the secondary coil Lp2 of the transformer T. The anode terminal of the diode Do2 is connected to the other terminal of the secondary coil Lp2. A center tap of the secondary coil Lp2 is connected to the other terminal of the smoothing capacitor Co and the other terminal of the load. Note that a configuration and operation of the current detection circuit 3 illustrated in FIG. 5 are the same as those of the current detection circuit 3 illustrated in FIG. 1, and thus, the description of the configuration and the operation will be omitted.

When the power converter 1 converts the DC power output from the power supply B to the specified DC power and supplies the specified DC power to the load, the switches Q1, Q2 are turned on and off alternately and repeatedly by the control circuit 2 illustrated in FIG. 5 so that a voltage across the smoothing capacitor Co reaches a target voltage and a current detected by the current detection circuit 3 reaches a target current. When the switch Q2 is turned off and the switch Q1 is turned on, a current flows from the power supply B to the primary coil Lp1 through the center tap of the primary coil Lp1, and a current flows from the secondary coil Lp2 to the load through the diode Do1 and the smoothing coil Lo. When the switch Q1 is turned off and the switch Q2 is turned on, a current flows from the power supply B to the primary coil Lp1 through the center tap of the primary coil Lp1, and a current flows from the secondary coil Lp2 to the load through the diode Do2 and the smoothing coil Lo.

Also in the power converter 1 illustrated in FIG. 5, when the detection circuit 4 detects the current flowing through the smoothing coil Lo, the power converter 1 need not have the function for offsetting a reference potential of the detection circuit 4 or a voltage across the detection capacitor Cd, so that the increase of the manufacturing costs of the power converter 1 is suppressed. In addition, also in the power converter 1 illustrated in FIG. 5, the voltage across the detection capacitor Cd increases as the turns ratio n increases, so that the voltage across the detection capacitor Cd is not easily affected by the quantization error in the detection circuit 4 when an analog value is converted to a digital value in the voltage across the detection capacitor Cd. This may improve the detection accuracy of the current. Also in the power converter 1 illustrated in FIG. 5, the current iL flowing through the smoothing coil Lo need not be corrected after being detected, and thus, the increase of the detection time of the current iL is suppressed.

### <Fourth Modification>

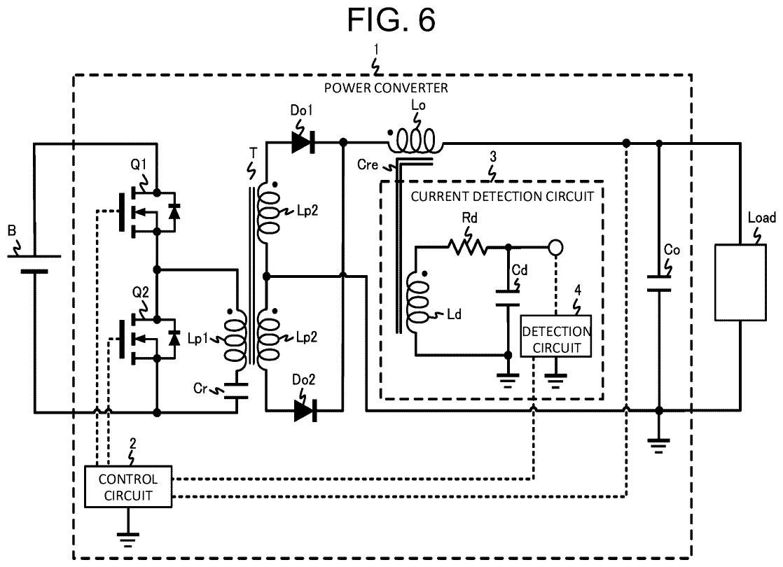

FIG. 6 is a diagram illustrating a fourth modification of the power converter 1 according to the embodiment. In FIG. 6, the same components as those illustrated in FIG. 1 have the same reference numerals and may not be reiterated.

The power converter 1 illustrated in FIG. 6 is an isolated half-bridge converter, and converts a DC power output from the power supply B to a specified DC power and supplies the specified DC power to the load.

That is, the power converter 1 illustrated in FIG. 6 includes the switches Q1, Q2, a capacitor Cr, the transformer T, the diodes Do1, Do2, the smoothing coil Lo, the smoothing capacitor Co, the control circuit 2, and the current detection circuit 3. The drain terminal of the switch Q1 is connected to the positive terminal of the power supply B, and the source terminal of the switch Q1 is connected to the drain terminal of the switch Q2 and the one terminal of the primary coil Lp1 of transformer T. The source terminal of the switch Q2 is connected to the other terminal of the primary coil Lp1 through the capacitor Cr and to the negative terminal of the power supply B. The cathode terminal of the diode Do1 is connected to the cathode terminal of the diode Do2. The cathode terminal of the diode Do1 is also connected to the one terminal of the smoothing capacitor Co and the one terminal of the load through the smoothing coil Lo. The anode terminal of the diode Do1 is connected to the one terminal of the secondary coil Lp2 of the transformer T. The anode terminal of the diode Do2 is connected to the other terminal of the secondary coil Lp2. The center tap of the secondary coil Lp2 is connected to the other terminal of the smoothing capacitor Co and the other terminal of the load. Note that a configuration and operation of the current detection circuit 3 illustrated in FIG. 6 are the same as those of the current detection circuit 3 illustrated in FIG. 1, and thus, the description of the configuration and the operation will be omitted.

In addition, when the power converter 1 converts the DC power output from the power supply B to the specified DC power and supplies the specified DC power to the load, the switches Q1, Q2 are turned on and off alternately and repeatedly by the control circuit 2 illustrated in FIG. 6 so that a voltage across the smoothing capacitor Co reaches a target voltage and a current detected by the current detection circuit 3 reaches a target current.

First, when the switch Q1 is turned on (when the switch Q1 is in the on-state and the switch Q2 is in the off-state), a current flows from the power supply B to the primary coil Lp1 through the switch Q1, and a current flows from the secondary coil Lp2 to the load through the diode Do1 and the smoothing coil Lo.

Next, when the switch Q1 is turned off (when the switches Q1, Q2 are in the off-state (deadtime)), a current flows from the other terminal of the primary coil Lp1 to the one terminal of the primary coil Lp1 through the capacitor Cr and the body diode of the switch Q2, and the current continuously flows from the secondary coil Lp2 to the load through the diode Do1 and the smoothing coil Lo.

Next, when the switch Q2 is turned on (when the switch Q1 is in the off-state and the switch Q2 is in the on-state), a current flows from the one terminal of the capacitor Cr to the other terminal of the capacitor Cr through the primary coil Lp1 and the switch Q2, and a current flows from the secondary coil Lp2 to the load through the diode Do2 and the smoothing coil Lo. Note that, when the switch Q2 is turned on, the current flows through the body diode of the switch Q2, and thus, the switching loss is reduced.

Next, when the switch Q2 is turned off (when the switches Q1, Q2 are in the off-state (deadtime)), a current flows from the negative terminal of the power supply B to the positive terminal of the power supply B through the capacitor Cr, the primary coil Lp1, and the body diode of the switch Q1, and the current continuously flows from the secondary coil Lp2 to the load through the diode Do2 and the smoothing coil Lo.

After that, the switches Q1, Q2 are turned on and off alternately and repeatedly. Note that, when the switch Q1 is turned on, the current flows through the body diode of the switch Q1, and thus, the switching loss is reduced.

Also in the power converter 1 illustrated in FIG. 6, when the detection circuit 4 detects the current flowing through the smoothing coil Lo, the power converter 1 need not have the function for offsetting a reference potential of the detection circuit 4 or a voltage across the detection capacitor Cd, so that the increase of the manufacturing costs of the power converter 1 is suppressed. In addition, also in the power converter 1 illustrated in FIG. 6, the voltage across the detection capacitor Cd increases as the turns ratio n increases, so that the voltage across the detection capacitor Cd is not easily affected by the quantization error in the detection circuit 4 when an analog value is converted to a digital value in the voltage across the detection capacitor Cd. This may improve the detection accuracy of the current. Also in the power converter 1 illustrated in FIG. 6, the current iL flowing through the smoothing coil Lo need not be corrected after being detected, and thus, the increase of the detection time of the current iL is suppressed.

### <Fifth Modification>

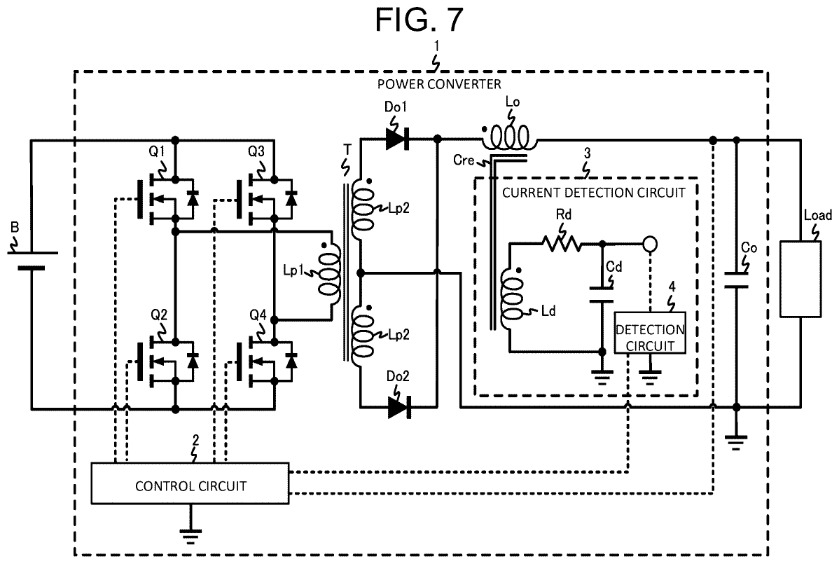

FIG. 7 is a diagram illustrating a fifth modification of the power converter 1 according to the embodiment. Note that in FIG. 7, the same components as those illustrated in FIG. 1 have the same reference numerals and may not be reiterated.

The power converter 1 illustrated in FIG. 7 is an isolated full-bridge converter, and converts a DC power output from the power supply B to a specified DC power and supplies the specified DC power to the load.

That is, the power converter 1 illustrated in FIG. 7 includes the switches Q1, Q2, switches Q3, Q4, the transformer T, the diodes Do1, Do2, the smoothing coil Lo, the smoothing capacitor Co, the control circuit 2, and the current detection circuit 3. Note that the switches Q3, Q4 are each formed of a MOSFET, for example. The drain terminal of the switch Q1 is connected to the positive terminal of the power supply B and a drain terminal of the switch Q3. The source terminal of the switch Q1 is connected to the one terminal of the primary coil Lp1 of the transformer T and the drain terminal of the switch Q2. The source terminal of the switch Q2 is connected to the negative terminal of the power supply B and a source terminal of the switch Q4. A source terminal of the switch Q3 is connected to the other terminal of the primary coil Lp1 and a drain terminal of switch Q4. The cathode terminal of the diode Do1 is connected to the cathode terminal of the diode Do2. The cathode terminal of the diode Do1 is also connected to the one terminal of the smoothing capacitor Co and the one terminal of the load through the smoothing coil Lo. The anode terminal of the diode Do1 is connected to the one terminal of the secondary coil Lp2 of the transformer T. The anode terminal of the diode Do2 is connected to the other terminal of the secondary coil Lp2. The center tap of the secondary coil Lp2 is connected to the other terminal of the smoothing capacitor Co and the other terminal of the load. Note that a configuration and operation of the current detection circuit 3 illustrated in FIG. 7 are the same as those of the current detection circuit 3 illustrated in FIG. 1, and thus, the description of the configuration and the operation will be omitted.

When the power converter 1 converts the DC power output from the power supply B to the specified DC power and supplies the specified DC power to the load, the switches Q1, Q4 are turned on and the switches Q2, Q3 are turned off, and then, the switches Q1, Q4 are turned off and the switches Q2, Q3 are turned on, by the control circuit 2 illustrated in FIG. 7. This switching operation is repeated so that a voltage across the smoothing capacitor Co reaches a target voltage and a current detected by the current detection circuit 3 reaches a target current. When the switches Q1, Q4 are turned on (when the switches Q1, Q4 are in the on-state and the switches Q2, Q3 are in the off-state), a current flows from the positive terminal of the power supply B to the negative terminal of the power supply B through the switch Q1, the primary coil Lp1, and the switch Q4, and a current flows from the secondary coil Lp2 to the load through the diode Do1 and the smoothing coil Lo. When the switches Q2, Q3 are turned on (when the switches Q1, Q4 are in the off-state and the switches Q2, Q3 are in the on-state), a current flows from the positive terminal of the power supply B to the negative terminal of the power supply B through the switch Q3, the primary coil Lp1, and the switch Q2, and a current flows from the secondary coil Lp2 to the load through the diode Do2 and the smoothing coil Lo.

Also in the power converter 1 illustrated in FIG. 7, when the detection circuit 4 detects the current flowing through the smoothing coil Lo, the power converter 1 need not have the function for offsetting a reference potential of the detection circuit 4 or a voltage across the detection capacitor Cd, so that the increase of the manufacturing costs of the power converter 1 is suppressed. In addition, also in the power converter 1 illustrated in FIG. 7, the voltage across the detection capacitor Cd increases as the turns ratio n increases, so that the voltage across the detection capacitor Cd is not easily affected by the quantization error in the detection circuit 4 when an analog value is converted to a digital value in the voltage across the detection capacitor Cd. This may improve the detection accuracy of the current. Also in the power converter 1 illustrated in FIG. 7, the current iL flowing through the smoothing coil Lo need not be corrected after being detected, and thus, the increase of the detection time of the current iL is suppressed.

### <Sixth Modification>

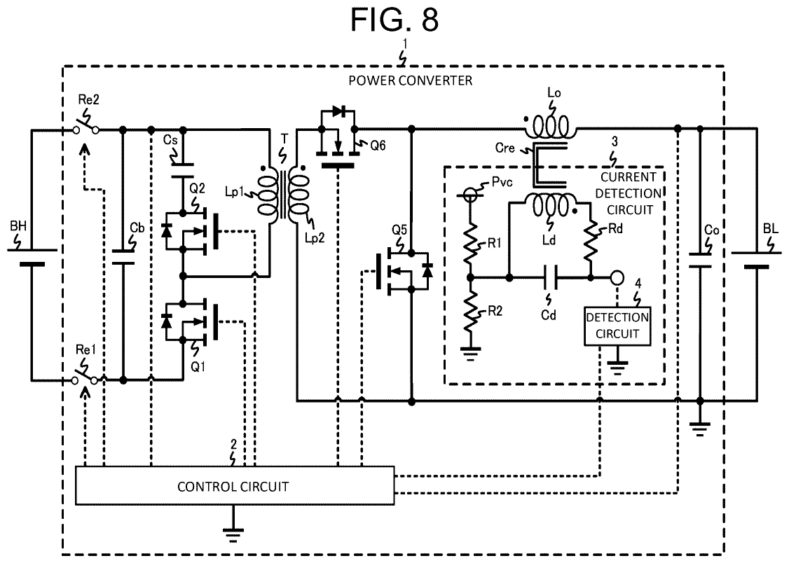

FIG. 8 is a diagram illustrating a sixth modification of the power converter 1 according to the embodiment. Note that in FIG. 8, the same components as those illustrated in FIG. 1 have the same reference numerals and may not be reiterated.

The power converter 1 illustrated in FIG. 8 is an active clamp forward converter, and converts a DC power output from a high voltage battery BH to a specified DC voltage and supplies the specified DC voltage to a low voltage battery BL.

That is, the power converter 1 illustrated in FIG. 8 includes relays Re1, Re2, a smoothing capacitor Cb, the switches Q1, Q2, the capacitor Cs, the transformer T, switches Q5, Q6, the smoothing coil Lo, the smoothing capacitor Co, the control circuit 2, and the current detection circuit 3. Note that the switches Q5, Q6 are each formed of a MOSFET, for example. The drain terminal of the switch Q1 is connected to the source terminal of the switch Q2 and the one terminal of the primary coil Lp1 of the transformer T, and the source terminal of the switch Q1 is connected to a negative terminal of the high voltage battery BH through the relay Re1 and to one terminal of the smoothing capacitor Cb. The drain terminal of the switch Q2 is connected to a positive terminal of the high voltage battery BH through the capacitor Cs and the relay Re2. The drain terminal of the switch Q2 is also connected to the other terminal of the primary coil Lp1 and the other terminal of the smoothing capacitor Cb through the capacitor Cs. A drain terminal of the switch Q5 is connected to a drain terminal of the switch Q6. The drain terminal of the switch Q5 is also connected to the one terminal of the smoothing capacitor Co and a positive terminal of the low voltage battery BL through the smoothing coil Lo. A source terminal of the switch Q5 is connected to the one terminal of the secondary coil Lp2 of the transformer T, the other terminal of the smoothing capacitor Co, and a negative terminal of the low voltage battery BL. A source terminal of the switch Q6 is connected to the other terminal of the secondary coil Lp2.

The current detection circuit 3 illustrated in FIG. 8 includes the detection coil Ld, the detection resistor Rd, the detection capacitor Cd, the detection circuit 4, and offset resistors R1, R2.

The detection coil Ld is wound around the core Cre of the smoothing coil Lo.

The detection resistor Rd and the detection capacitor Cd are connected in series to each other and are connected in parallel to the detection coil Ld.

The offset resistors R1, R2 are connected between a constant voltage power supply Pvc and a reference potential of the detection circuit 4 in series to each other. A node between the offset resistors R1, R2 is connected to a node between the detection coil Ld and the detection capacitor Cd. Thus, a total voltage of a voltage across the detection capacitor Cd and a voltage across the offset resistor R2 is input to the detection circuit 4. That is, due to the offset resistors R1, R2, the voltage across the detection capacitor Cd is offset by a difference between an electric potential at the node between the offset resistors R1, R2 and the reference potential of the detection circuit 4, and the voltage of the detection capacitor Cd after being offset is input to the detection circuit 4. The detection circuit 4 substitutes the voltage Vc across the detection capacitor Cd, which have been offset, into the above-described Equation 2 to obtain the current iL flowing through the smoothing coil Lo. Accordingly, while the current flowing in a forward direction through the smoothing coil Lo is detected based on a voltage higher than the electric potential at the node between the offset resistors R1, R2, of the voltage input to the detection circuit 4, the current in a reverse direction flowing through the smoothing coil Lo is detected based on a voltage lower than the electric potential at the node between the offset resistors R1, R2, of the voltage input to the detection circuit 4.

In the power converter 1 illustrated in FIG. 8, the electric potential at the smoothing capacitor Cb is zero before the power converter 1 starts up. Before a normal operation in which the DC power output from the high voltage battery BH is converted to the specified DC power and the specified DC power is supplied to the low voltage battery BL, the relays Re1, Re2 are set in an electrically disconnected state by the control circuit 2 and the smoothing capacitor Cb is charged in advance by a power supplied from the low voltage battery BL. After that, the relays Re1, Re2 are set in an electrically connected state by the control circuit 2 and the power is supplied from the high voltage battery BH to the low voltage battery BL. With this operation, when the relays Re1, Re2 are transitioned from the electrically disconnected state to the electrically connected state, it is suppressed that a relatively large inrush current flows from the high voltage battery BH into the smoothing capacitor Cb.

For example, it is assumed that a direction in which a current flows from the high voltage battery BH to the low voltage battery BL is defined as the forward direction, and a direction in which a current flows from the low voltage battery BL to the high voltage battery BH is defined as the reverse direction. Furthermore, a range of an input voltage of the detection circuit 4 for an analog-to digital conversion thereof is defined as a range from 0 [V] to 5 [V], and the electric potential at the node between the offset resistors R1, R2 is defined as 2.5 [V]. The voltage across the detection capacitor Cd after being offset is represented as Vc.

In this case, first, the relays Re1, Re2 are turned off by the control circuit 2, and the switch Q1 is constantly turned off and the switches Q2, Q5, Q6 are turned on and off repeatedly by the control circuit 2 so that the current in the reverse direction detected by the current detection circuit 3 reaches a target value. When the switch Q6 is turned on (when the switches Q1, Q2, Q5 are in the off-state and the switch Q6 is in the on-state), a current flows from the low voltage battery BL to the secondary coil Lp2, and a current flows from the primary coil Lp1 through the smoothing capacitor Cb. At this time, a direction of the current flowing through the smoothing coil Lo is the reverse direction. When the switch Q6 is turned off (when the switches Q1, Q6 are in the off-state and the switches Q2, Q5 are in the on-state), the transformer T is reset and the current flowing in the reverse direction through the smoothing coil Lo increases. That is, also in this case, the direction of the current flowing through the smoothing coil Lo is the reverse direction. Accordingly, the voltage input to the detection circuit 4 is lower than 2.5 [V] and equal to or higher than 0 [V], so that the detection circuit 4 detects the current flowing in the reverse direction through the smoothing coil Lo. This allows the smoothing capacitor Cb to be charged before the relays Re1, Re2 are set in the electrically connected state. Note that the switch Q1 may be turned on and off in synchronization with the switch Q6.

Next, when the voltage across the smoothing capacitor Cb is a threshold voltage (for example, a voltage of the high voltage battery BH) or more, the control circuit 2 sets the relays Re1, Re2 in the electrically connected state.

Then, the switches Q5, Q6 are turned on and off alternately and repeatedly and the switches Q1, Q2 are turned on and off alternately and repeatedly by the control circuit 2 so that the voltage across the smoothing capacitor Co reaches a target voltage and the current detected in the forward direction by the current detection circuit 3 reaches a target current. When the switches Q1, Q6 are turned on (when the switches Q1, Q6 are in the on-state and the switches Q2, Q5 are in the off-state), a current flows from the high voltage battery BH to the primary coil Lp1, and a current flows from the secondary coil Lp2 to the low voltage battery BL through the switch Q6 and the smoothing coil Lo. When the switch Q2 is turned on (when the switches Q1, Q6 are in the off-state and the switches Q2, Q5 are in the on-state), a current flows from the primary coil Lp1 to the capacitor Cs through the switch Q2, so that the transformer T in a magnetic saturation state is gradually demagnetized. In addition, on a side of the low voltage battery BL, a current flows from the switch Q5 to the low voltage battery BL through the smoothing coil Lo. Here, the voltage input to the detection circuit 4 is higher than 2.5 [V] and equal to or lower than 5 [V], and the detection circuit 4 detects the current in the forward direction flowing through the smoothing coil Lo.

Also in the power converter 1 illustrated in FIG. 8, the voltage across the detection capacitor Cd increases as the turns ratio n increases, so that the voltage across the detection capacitor Cd is not easily affected by the quantization error in the detection circuit 4 when an analog value is converted to a digital value in the voltage across the detection capacitor Cd. This may improve the detection accuracy of the current. Also in the power converter 1 illustrated in FIG. 8, the current iL flowing through the smoothing coil Lo need not be corrected after being detected, and thus, the increase of the detection time of the current iL is suppressed.

What is claimed is:

1. A power converter including a coil comprising:
a detection coil that is magnetically coupled to the coil;
a detection resistor and a detection capacitor that are connected in series to each other and in parallel to the detection coil; and
a detection circuit that detects a current flowing through the coil based on a voltage across the detection capacitor.

2. The power converter according to claim 1, wherein
the coil is a smoothing coil by which the current flowing in the power converter is smoothed.

3. The power converter according to claim 2, wherein
the smoothing coil has a core, and
the detection coil is formed by being wound around the core.

4. The power converter according to claim 3, wherein
the core has a gap.

5. The power converter according to claim 1, wherein
in a case where the number of turns of the coil represents N1 and the number of turns of the detection coil represents N2, N2/N1 is equal to or less than 10.

6. The power converter according to claim 1, further comprising
two offset resistors that are connected between a constant voltage source and a reference potential of the detection circuit in series to each other, wherein
the two offset resistors offset the voltage across the detection capacitor by a difference between an electric potential at a node between the two offset resistors and the reference potential of the detection circuit.

7. The power converter according to claim 2, wherein
the smoothing coil is disposed on at least one of main surfaces of a printed circuit board on which the power converter is mounted, and
the detection coil is arranged relative to the smoothing coil in a thickness direction of the printed circuit board.

8. The power converter according to claim 7, wherein
the printed circuit board is a multilayer printed circuit board, and
the detection coil is disposed on an inner layer of the printed circuit board as a wiring pattern.

9. A current detection circuit for detecting a current flowing through a coil provided in a power converter, the current detection circuit comprising:
a detection coil that is magnetically coupled to the coil;
a detection resistor and a detection capacitor that are connected in series to each other and in parallel to the detection coil; and
a detection circuit that detects a current flowing through the coil based on a voltage across the detection capacitor.
